(19) United States
(12) Patent Application Publication
(10) Pub. No.: US 2015/0100263 A1
(43) Pub. Date: Apr. 9, 2015

(54) METHOD FOR MEASURING A MAGNETIC FIELD BY MEANS OF A SWITCHING HALL-EFFECT SENSOR

(71) Applicants: Simon-Didier VENZAL, TOULOUSE (FR); Xavier HOURNE, CUGNAUX (FR)

(72) Inventors: Simon-Didier VENZAL, TOULOUSE (FR); Xavier HOURNE, CUGNAUX (FR)

(73) Assignees: CONTINENTAL AUTOMOTIVE GMBH, Hannover (DE); CONTINENTAL AUTOMOTIVE FRANCE, Toulouse (FR)

(21) Appl. No.: 14/496,094

(22) Filed: Sep. 25, 2014

(30) Foreign Application Priority Data
Oct. 8, 2013 (FR) 1359757

(51) Int. Cl. G01R 33/07

(52) U.S. Cl. CPC G01R 33/07
USPC 702/65

(57) ABSTRACT

A method for measuring a magnetic field via a Hall cross (12) including two orthogonal branches (120, 122), in which, for a given state of the Hall cross, a polarization current is made to flow in one of the branches of the Hall cross, referred to as the “polarization branch”, and a voltage is measured in the other branch, referred to as the “measurement branch”, the measured voltage including a useful signal representing the magnetic field, the method including the modulation of the useful signal via a switching sequence consisting in placing the Hall cross in Nb successive states, and the demodulation of the useful signal. The switching sequence is furthermore chosen in such a way that a measurement bias and interference pulses are zero-mean after demodulation. A switching Hall-effect sensor (10) is also described.

### FIELD OF THE INVENTION

The present invention relates to the field of measurement sensors, and concerns more particularly a method for measuring a magnetic field by means of a switching Hall-effect sensor.

### BACKGROUND OF THE INVENTION

In a known manner, a switching Hall-effect sensor comprises a Hall cross sensitive to a magnetic field which delivers a voltage proportional to the intensity of the magnetic field in which said Hall cross is located. When the magnetic field is induced by the flow of a current, for example, the magnetic field measured by means of the Hall cross then allows the intensity of this current to be estimated.

A Hall cross comprises, in a known manner, two more or less orthogonal branches each comprising two terminals. At a given time, one of the two branches, known as the “polarization branch”, is used to polarize said Hall cross by causing a polarization current of predetermined intensity to flow in the polarization branch. The voltage on the terminals of the other branch, known as the “measurement branch”, is then measured and represents the magnetic field.

The switching Hall-effect sensor furthermore comprises a polarization circuit, comprising notably a switch network suitable for connecting any one of the branches of the Hall cross to a polarization current source. Thus, each branch of the Hall cross can be implemented alternately as a polarization branch. Moreover, the switch network of the polarization circuit is suitable for reversing the connection of the terminals of the polarization branch in order to reverse the direction of flow of the polarization current.

The switching Hall-effect sensor furthermore comprises a measurement circuit, comprising notably a switch network suitable for measuring the voltage on the terminals of any one of the branches of the Hall cross. Thus, each branch of the Hall cross can be implemented alternately as a measurement branch. Moreover, the switch network of the measurement circuit is suitable for reversing the connection of the terminals of the measurement branch in order to reverse the direction of measurement of the voltage on the terminals of the measurement branch.

In total, the polarization circuit and the measurement circuit enable the Hall cross to be placed in eight different states which depend on the branch of said Hall cross which is implemented as a polarization branch (the other branch being implemented as a measurement branch), on the direction of flow of the polarization current in the polarization branch and on the direction of measurement of the voltage on the terminals of the measurement branch.

It is known that the voltage measured on the terminals of the measurement branch breaks down into a useful signal, representing the magnetic field to be measured, to which a measurement bias intrinsic to the Hall cross is added.

One solution for eliminating the measurement bias consists in applying a switching sequence consisting of a plurality of successive states of the Hall cross, chosen in such a way that, with each transition between two successive states of said switching sequence:
the polarization branch and the measurement branch of the Hall cross are swapped, i.e. the branch previously implemented as the polarization branch becomes the measurement branch and vice versa,
the mutual orientation of the measurement direction of the voltage, in relation to the polarization direction, is reversed.

Thus, and in a known manner, the useful signal is modulated by a zero-mean, square-wave signal with a frequency equal to the switching frequency of the switching sequence, whereas the measurement bias is not modulated. Thus, the useful signal and the measurement bias are frequency-separated, respectively adjusted around the switching frequency and the zero frequency. By demodulating the voltage measured by said square-wave signal, the useful signal is then adjusted around the zero frequency whereas the measurement bias is modulated by the square-wave signal and adjusted around the switching frequency. Thus, a suitable low-pass filtering eliminates the measurement bias while retaining the useful signal.

However, each swap of the polarization and measurement branches of the Hall cross also adds an interference pulse to the useful signal, immediately after the swap. This interference pulse is generated by the discharge to the measurement circuit of stray capacitances charged, prior to the swap, by the polarization current. These interference pulses are not compensated by the demodulation and low-pass filtering, and are the cause of a residual bias which interferes with the estimation of the magnetic field.

To solve this problem, it is then known to use a sample-and-hold circuit which holds the measured voltage just before each swap of the polarization and measurement branches, and for the entire predetermined duration of the interference pulses. The interference pulses induced by the stray capacitances upstream of the sample-and-hold circuit are thus eliminated. However, this solution has disadvantages, insofar as:
it is necessary to add components to the switching Hall-effect sensor, which increases the cost and complexity thereof,
the bandwidth of the switching Hall-effect sensor is limited due to the absence of observation of the voltage on the terminals of the measurement branch during the hold,
the sample-and-hold circuit also comprises stray capacitances which in turn introduce interference pulses,
the duration and amplitude of the interference pulses depend on the temperature of the switching Hall-effect sensor, in such a way that the control of the sample-and-hold circuit is complex.

The object of the present invention is to overcome all or some of the limitations of the prior art solutions, notably those described above.

### SUMMARY OF THE INVENTION

To do this, and according to a first aspect, the present invention relates to a method for measuring a magnetic field by means of a Hall cross including two orthogonal branches, in which, for a given state of the Hall cross, a polarization current is made to flow in one of the branches of the Hall cross, referred to as the “polarization branch”, and a voltage is measured in the other branch, referred to as the “measurement branch”, said measured voltage comprising a useful signal representing the magnetic field, said method comprising the modulation of the useful signal by means of a switching sequence consisting in placing the Hall cross in a number Nb of successive states, and the demodulation of said useful signal. By defining:
a reference point x, y, z associated with the Hall cross, in which x is a vector parallel to one of the two branches of the Hall cross, y is a vector parallel to the other of the two branches, and z is a vector equal to x̂y, where “̂” corresponds to the vector product,
a state E(n) of the Hall cross at a time n in the form of unit vectors i(n) and v(n) corresponding respectively to the direction of flow of the polarization current in the polarization branch and to the direction of measurement of the voltage on the terminals of the measurement branch, expressed in the reference point,
a mutual orientation IV(n) of the vectors i(n) and v(n) in the reference point as being equal to (i(n)̂v(n))·z, where “·” corresponds to the scalar product,
a swap P(n) between the state E(n−1) and the state E(n) as being equal to v(n)·i(n−1),

the switching sequence is then such that, with each transition between two successive states, the polarity of the mutual orientation is reversed, and such that the following two expressions are verified:

$${\sum }_{n = 0}^{Nb - 1} {( - 1 )}^{n} \times P ( n ) = 0$$

$$1 + {\sum }_{n = 1}^{Nb - 1} {( - 1 )}^{H ( n )} = 0$$

where:

$$H ( n ) = {\sum }_{k = 1}^{n} \vert P ( k ) \vert .$$

Moreover, the invention proposes that the measurement method furthermore comprises the following characteristics, taken in combination.

The switching sequence, the swap P(n) is zero in every other state and the polarity reversal of the mutual orientation IV(n) in relation to the mutual orientation IV(n−1) is obtained, when the swap P(n) is zero, by reversing the direction of flow of the polarization current in the polarization branch of the Hall cross.

And the number Nb of successive states is equal to 4, and a number k exists, such that:

P(k[Nb])=1

P((k+1)[Nb])=0

P((k+2)[Nb])=−1

P((k+3)[Nb])=0

where “[Nb]” means modulo Nb.

Such measures are advantageous in that they ensure that the measurement bias and the residual bias, induced by the interference pulses during the swaps of the polarization and measurement branches, can be distinguished from the useful signal, for example by means of a low-pass filtering. In fact, the two expressions verified by the switching sequence concerned ensure that, following demodulation:
the number of intervals during which the measurement bias is positive is equal to the number of intervals during which said measurement bias is negative, in this case equal to Nb/2,
the number of positive interference pulses is equal to the number of negative interference pulses.

Furthermore, such measures ensure a uniform ageing of the Hall cross. In fact, each branch of the Hall cross, when used as a polarization branch, is then systematically submitted to a polarization current flowing in both possible directions.

According to a second aspect, the present invention relates to a switching Hall-effect sensor comprising a Hall cross including two orthogonal branches. The switching Hall-effect sensor furthermore comprises means configured to measure a useful signal, representing the magnetic field in which the Hall cross is placed, by carrying out a method for measuring a magnetic field according to the invention.

According to a third aspect, the present invention relates to a motor vehicle comprising a switching Hall-effect sensor according to the invention.

### BRIEF DESCRIPTION OF THE DRAWINGS

The invention will be better understood from a reading of the following description, given as a non-limiting example and referring to the figures in which:

FIG. 1 is a schematic representation of an example embodiment of a switching Hall-effect sensor,

FIG. 2 is a schematic representation of the different possible states of a Hall cross comprising two branches,

FIG. 3 is a time diagram showing the operation of a switching Hall-effect sensor 10 according to the invention.

### DETAILED DESCRIPTION OF THE INVENTION

In these figures, identical references from one figure to another denote identical or corresponding elements. For reasons of clarity, the elements shown are not drawn to scale, unless otherwise specified.

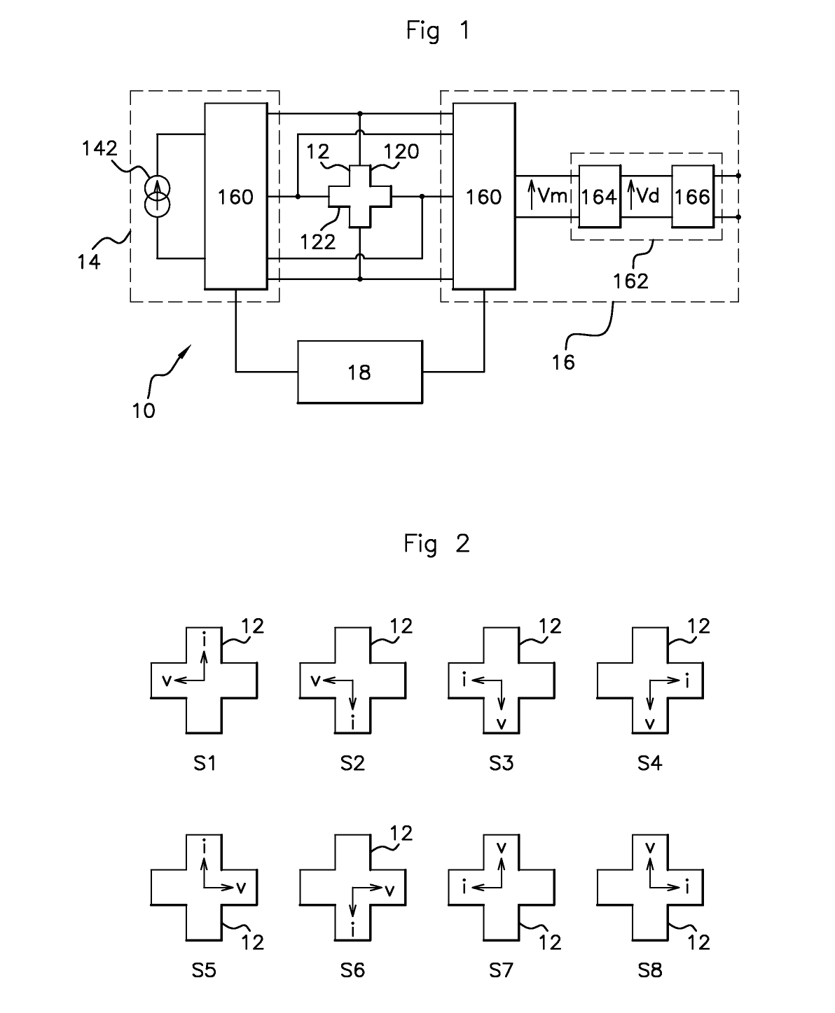

FIG. 1 shows an example embodiment of a switching Hall-effect sensor 10. A switching Hall-effect sensor 10 of this type is, for example, in a non-limiting manner, installed on-board a motor vehicle.

As shown in FIG. 1, the switching Hall-effect sensor 10 notably comprises a Hall cross 12, a polarization circuit 14, a measurement circuit 16 and a control circuit 18.

The Hall cross 12 comprises two more or less orthogonal branches 120, 122, each comprising two terminals.

The polarization circuit 14 comprises, for example, a switch network 140 suitable for connecting any one of the branches 120, 122 of the Hall cross 12 to a polarization current source 142. The branch 120, 122 of the Hall cross 12 thus connected, at a given time, to the polarization current source 142 is referred to as the “polarization branch”.

Moreover, the switch network 140 of the polarization circuit 14 is suitable for reversing the connection of the terminals of the polarization branch to the polarization current source 142 in said polarization branch in such a way as to reverse the direction of flow of the polarization current in said polarization branch.

The measurement circuit 16 comprises, for example, a switch network 160 suitable for connecting any one of the branches 120, 122 of the Hall cross 12 to a processing module 162. The branch 120, 122 of the Hall cross 12 thus connected, at a given time, to the processing module 162 is referred to as the “measurement branch”.

Moreover, the switch network 160 of the measurement circuit 16 is suitable for reversing the connection of the terminals of the measurement branch to the processing module 162 in such a way as to reverse the direction of measurement, by the processing module 162, of the voltage on the terminals of said measurement branch.

The control circuit 18 is suitable for controlling the switch networks 140, 160 of the polarization circuit 14 and of the measurement circuit 16 in such a way as to select the polarization branch and the measurement branch of the Hall cross, and also the direction of flow of the polarization current and the direction of measurement of the voltage on the terminals of the measurement branch.

In total, the control circuit 18 can place the Hall cross 12 in eight different states, which depend on the branch selected as the polarization branch (the other branch of the Hall cross then being the measurement branch), the direction of flow of the polarization currents and the direction of measurement of the voltage on the terminals of the measurement branch.

FIG. 2 shows schematically the eight possible states S1 to S8 of the Hall cross 12.

In the description below, a reference point x, y, z is associated with the Hall cross 12, visible in FIG. 2, in which:
x is a unit vector parallel to one of the two branches,
y is a unit vector parallel to the other of the two branches,
z is a unit vector equal to z=x̂y, i.e. equal to the vector product of the vector x by the vector y.

The different states S1 to S8 of the Hall cross 12 may be defined in the form of unit vectors i and v corresponding respectively to the direction of flow of the polarization current in the polarization branch and to the direction of measurement of the voltage on the terminals of the measurement branch, expressed in the reference point. The state E(n) of the Hall cross 12 at a time n can therefore assume any one of the states S1 to S8.

Furthermore, the following are defined:
a mutual orientation IV(n) of the vectors i(n) and v(n) at the time n in the reference point as being equal to IV(n)=(i(n)̂v(n))·z, where “·” corresponds to the scalar product of two vectors,
a swap P(n) between the state E(n−1) and the state E(n) as being equal to P(n)=v(n)·i(n−1).

The following table gives the expressions of the states S1 to S8 in the reference point (x, y, z) associated with the Hall cross, and also, for each state, the associated mutual orientation IV:

| State | i | v | IV |
|---|---|---|---|
| S1 | (0, 1, 0) | (−1, 0, 0) | 1 |
| S2 | (0, −1, 0) | (−1, 0, 0) | −1 |
| S3 | (−1, 0, 0) | (0, −1, 0) | 1 |
| S4 | (1, 0, 0) | (0, −1, 0) | −1 |
| S5 | (0, 1, 0) | (1, 0, 0) | −1 |
| S6 | (0, −1, 0) | (1, 0, 0) | 1 |
| S7 | (−1, 0, 0) | (0, 1, 0) | −1 |
| S8 | (1, 0, 0) | (0, 1, 0) | 1 |

As previously indicated, the measured voltage Vm comprises a useful signal Vu representing the magnetic field in which the Hall cross 12 is placed, and also:
a measurement bias Vb intrinsic to the Hall cross 12,
an interference pulse Vimp immediately after a swap of the polarization and measurement branches.

The control circuit 18 controls said switch networks 140, 160 in such a way as to apply a switching sequence consisting in placing the Hall cross 12 in an even number Nb of successive states, at a predefined switching frequency Fc. The switching sequence is preferably applied cyclically, i.e. when the last state of the switching sequence is reached, the performance of said switching sequence resumes from its first state.

More particularly, the switching sequence is chosen in such a way as to modulate the useful signal Vu in such a way as to reverse the polarity on each transition between two successive states of the switching sequence. Thus, the useful signal Vu is modulated by a zero-mean, square-wave signal with a frequency equal to the switching frequency Fc. Thus, the useful signal is centered around the switching frequency Fc. In practice, for a given magnetic field, the polarity of the useful signal Vu depends only on the mutual orientation IV of the state concerned. Consequently, a polarity reversal of the useful signal Vu is obtained by means of a switching sequence for which the polarity of the mutual orientation is reversed on each transition. In other words, the switching sequence must be such that, for any value of n in [0, Nb−1]:

IV(n)×IV((n−1)[Nb])=−1

where “[Nb]” means modulo Nb.

Many switching sequences are consequently possible, for example the following switching sequences:
S1, S2, S3, S4
S5, S6, S7, S8
etc.

The processing module 162 then comprises a demodulator circuit 164 suitable for frequency-translating the useful signal Vu in such a way as to center it on the zero frequency. Many implementations are possible for realizing the demodulator circuit 164, considered to be within the range of the person skilled in the art.

The processing module 162 furthermore preferably comprises a low-pass filter 166 suitable for reducing the contributions of the signals whose frequencies are much higher than the bandwidth required for the switching Hall-effect sensor.

In practice, the variation of the measurement bias from one state to another of the switching sequence depends not only on the variation of the mutual orientation IV, but also on the swap P. More particularly, it has been verified that, before demodulation and for any value of n in [0, Nb−1]:

Vb(n)=Vb((n−1)[Nb])×IV(n)×IV((n−1)[Nb])×(−1)^{|P(n)|}

Consequently, after demodulation, the following is obtained:

Vb(n)=Vb((n−1)[Nb])×(−1)^{|P(n)|}

Moreover, it has been verified that, before modulation and for any value of n in [0, Nb−1], the interference pulse Vimp(n) at a time n corresponds to the swap P(n). Thus, in the absence of a swap between the time (n−1) and the time n, Vimp(n) is equal to zero. In the presence of a swap, the polarity of the interference pulse Vimp(n) varies like that of the swap P(n). More particularly, it has been verified that, before demodulation and for any value of n in [0, Nb−1]:

Vimp(n)=P(n)

Consequently, after demodulation, the following is obtained:

Vimp(n)=(−1)ⁿ×P(n)

It will therefore be understood that the variations of the useful signal Vu, of the measurement bias Vb and of the interference pulses Vimp may differ from one another for each transition of the switching sequence. Consequently, the switching sequences, discussed above, enabling modulation of the useful signal Vu, do not necessarily all have the same properties in terms of capability to suppress the measurement bias and interference pulses.

In particular, any switching sequence such that the measurement bias Vb and the interference pulses Vimp are zero-mean after demodulation will enable said useful signal Vu to be distinguished from said measurement bias and said interference pulses.

By denoting as VO the measurement bias value at the time 0 (Vb(0)=VO), then, after demodulation and for any value of n in [1, Nb−1]:

Vb(n)=VO×(−1)^{H(n)}

where:

$$H ( n ) = {\sum }_{k = 1}^{n} \vert P ( k ) \vert$$

The measurement bias Vb is zero-mean after demodulation, if:

$${\sum }_{n = 0}^{Nb - 1} Vb ( n ) = 0$$

which, according to the preceding expressions, gives a switching sequence which verifies the following expression:

$$1 + {\sum }_{n = 1}^{Nb - 1} {( - 1 )}^{H ( n )} = 0$$

The interference pulses Vimp are zero-mean after demodulation, if:

$${\sum }_{n = 0}^{Nb - 1} Vimp ( n ) = 0$$

which, according to the preceding expressions, gives a switching sequence which verifies the following expression:

$${\sum }_{n = 0}^{Nb - 1} {( - 1 )}^{n} \times P ( n ) = 0$$

Consequently, the control circuit 18 preferably implements a switching sequence such that, with each transition between two successive states, the polarity of the mutual orientation is reversed, and such that the following two expressions are verified:

$${\sum }_{n = 0}^{Nb - 1} {( - 1 )}^{n} \times P ( n ) = 0$$

$$1 + {\sum }_{n = 1}^{Nb - 1} {( - 1 )}^{H ( n )} = 0$$

With such a switching sequence, the measurement bias Vb and the interference pulses Vimp are zero-mean after demodulation, and the useful signal Vu is in the baseband, in the vicinity of the zero frequency. It is consequently possible to eliminate the measurement bias Vb and the interference pulses Vimp by means of the low-pass filter 166, or at least to reduce them substantially in relation to the useful signal Vu.

In preferred embodiments, in the switching sequence, the swap P(n) is furthermore zero in every other state. The polarity reversal of the mutual orientation IV(n) in relation to the mutual orientation IV(n−1) is furthermore obtained, when the swap P(n) is zero, by reversing the direction of flow of the polarization current in the polarization branch of the Hall cross. Thus, each branch of the Hall cross 12, when used as a polarization branch, is then systematically submitted to a polarization current flowing in the two possible directions, in such a way that the aging of the Hall cross is more uniform.

In the case where the number Nb of states is equal to four, possible switching sequences are such that:

P(k[Nb])=1

P((k+1)[Nb])=0

P((k+2)[Nb])=−1

P((k+3)[Nb])=0

for any value of k in [0, 3]. It can easily be shown that the preceding expressions are verified. Moreover, if, each time that the swap P(n) is zero, the polarity reversal of the mutual orientation is obtained by reversing the direction of flow of the polarization current in the polarization branch of the Hall cross 12, a uniform ageing of the Hall cross 12 is furthermore ensured.

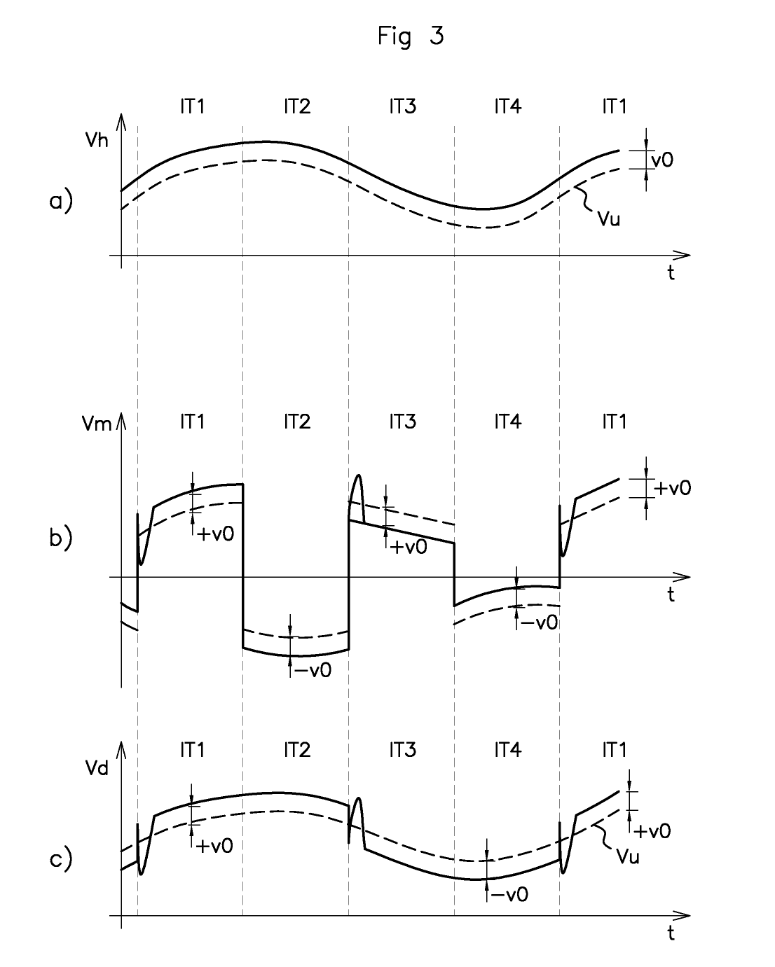

FIG. 3 illustrates the operation of the switching Hall-effect sensor 10, in the case where the switching sequence comprises the following four states:

| | E(n) | P(n) |
|---|---|---|
| n = 0 | S1 | −1 |
| n = 1 | S2 | 0 |
| n = 2 | S3 | 1 |
| n = 3 | S4 | 0 |

It must be noted that, since the switching sequence is applied cyclically, the swap P(0) corresponds to the transition between the state S4 and the state S1. Moreover, it is evident that, when the swap P(n) is zero, the polarity reversal of the mutual orientation is obtained by reversing the direction of flow of the polarization current (transition from S1 to S2, and transition from S3 to S4). Consequently, the switching sequence S1, S2, S3, S4 is furthermore optimum from a point of view of the aging of the Hall cross 12.

It must be noted that, due to the fact that the swap P(n) is zero in every other state, the measurement bias Vb, after demodulation, changes polarity only in every other state. Consequently, the measurement bias Vb after demodulation is centered on the frequency Fc/2, and the cut-off frequency of the low-pass filter 166 must preferably be chosen as less than Fc/2 in order to eliminate most effectively said measurement bias Vb. The switching frequency Fc must consequently be chosen in such a way as to ensure the required bandwidth for the switching Hall-effect sensor 10, while enabling the elimination of the measurement bias Vb centered on the frequency Fc/2.

Part a) of FIG. 3 shows the voltage Vh that would be measured, without a switching sequence, by placing the Hall cross 12 in the state S1 for the entire duration of the measurement. More particularly, part a) shows the useful signal Vu by broken lines, and the measured voltage Vh by continuous lines. Since, in part a), the polarization and measurement branches are never swapped, the measured voltage Vh does comprises no interference pulses. Moreover, in the example shown by part a) of FIG. 3, the measurement bias VO is positive.

Part b) of FIG. 3 shows the measured voltage before demodulation, this time by applying the switching sequence described above, the states S1, S2, S3 and S4 being applied during respective time intervals IT1, IT2, IT3 and IT4.

At the beginning of the interval IT1, the measured voltage Vm comprises a negative interference pulse corresponding to the transition between the preceding state S4 and the current state S1. The useful signal Vu is positive during the interval IT1, as in part a). The measurement bias Vb is also positive as in part a), equal to VO.

Since the polarization and measurement branches are not swapped, the measured voltage Vm comprises no interference pulses at the beginning of the interval IT2. On the other hand, due to the modulation, the useful signal Vu and the measurement bias Vb are negative during the interval IT2.

At the beginning of the interval IT3, the measured voltage Vm comprises a positive interference pulse corresponding to the transition between the preceding state S2 and the current state S3. The useful signal Vu is again positive during the interval IT1, as in part a). The measurement bias Vb is itself still negative, equal to −VO, as during the interval IT2.

Since the polarization and measurement branches are not swapped, the measured voltage Vm comprises no interference pulses at the beginning of the interval IT4. The useful signal Vu, on the other hand, is negative, as during the interval IT2. The measurement bias Vb is itself again positive, as during the interval IT1, equal to VO.

Part c) of FIG. 3 shows the voltage Vd obtained after demodulation of the voltage Vm of part b) of FIG. 3. More particularly, the voltage Vd is equal to the voltage Vm during the intervals IT1 and IT3, and equal to −Vm during the intervals IT2 and IT4. Consequently:
during the interval IT1: the voltage Vd comprises a negative interference pulse, the useful signal Vu and the measurement bias Vb are both positive,
during the interval IT2: the voltage Vd comprises no interference pulses, the useful signal Vu and the measurement bias Vb are both positive,
during the interval IT3: the voltage Vd comprises a positive interference pulse, the useful signal Vu is positive and the measurement bias Vb is negative,
during the interval IT4: the voltage Vd comprises no positive interference pulses, the useful signal Vu is positive and the measurement bias Vb is negative.

It is evident therefore that the voltage Vd corresponds to the useful signal Vu, affected by a measurement bias Vb and interference pulses. However, over the period 4/Fc of the switching sequence, the measurement bias Vb is zero-mean, as are the interference pulses. Consequently, a low-pass filter 166 with an adapted cut-off frequency, for example equal to Fc/4, substantially reduces the measurement bias Vb and the interference pulses.

More generally, it should be noted that the embodiments considered below have been described as non-limiting examples, and that other variants are consequently conceivable.

The invention has notably been described by considering mainly a switching sequence comprising a number Nb of states equal to four. According to other examples, consideration of a number Nb of states other than four is in no way excluded. However, it must be noted that a switching sequence ensuring a uniform ageing of the Hall cross must comprise at least four states.

The description above clearly illustrates that, through its different characteristics and their advantages, the present invention achieves the goals that it had set itself. In particular, by means of a particularly advantageous switching sequence, the measurement bias and interference pulses can simply be eliminated without having to add components such as a sample-and-hold circuit.

1. A method for measuring a magnetic field by means of a Hall cross (12) including two orthogonal branches (120, 122), in which, for a given state of the Hall cross, a polarization current is made to flow in one of the branches (120, 122) of the Hall cross, referred to as the “polarization branch”, and a voltage is measured in the other branch (120, 122), referred to as the “measurement branch”, said measured voltage comprising a useful signal (Vu) representing the magnetic field, said method comprising the modulation of the useful signal (Vu) by means of a switching sequence consisting in placing the Hall cross in a number Nb of successive states, and the demodulation of said useful signal (Vu), by defining:
a reference point x, y, z associated with the Hall cross, in which x is a unit vector parallel to one of the two branches (120, 122) of the Hall cross, y is a unit vector parallel to the other of the two branches (120, 122), and z is a unit vector equal to x̂y, where “̂” corresponds to the vector product,
a state E(n) of the Hall cross at a time n in the form of unit vectors i(n) and v(n) corresponding respectively to the direction of flow of the polarization current in the polarization branch (120, 122) and to the direction of measurement of the voltage on the terminals of the measurement branch (120, 122), expressed in the reference point,
a mutual orientation IV(n) of the vectors i(n) and v(n) in the reference point as being equal to (i(n)̂v(n))·z, where “·” corresponds to the scalar product,
a swap P(n) between the state E(n−1) and the state E(n) as being equal to v(n)·i(n−1),
the switching sequence is such that, with each transition between two successive states, the polarity of the mutual orientation is reversed, and such that the following two expressions are verified:
$${\sum }_{n = 0}^{Nb - 1} {( - 1 )}^{n} \times P ( n ) = 0$$
$$1 + {\sum }_{n = 1}^{Nb - 1} {( - 1 )}^{H ( n )} = 0$$
where:
$$H ( n ) = {\sum }_{k = 1}^{n} \vert P ( k ) \vert$$
the method being characterized in that:
in the switching sequence, the swap P(n) is zero in every other state and the polarity reversal of the mutual orientation IV(n) in relation to the mutual orientation IV(n−1) is obtained, when the swap P(n) is zero, by reversing the direction of flow of the polarization current in the polarization branch (120, 122) of the Hall cross, and
Nb is equal to four, and a number k exists, such that:
P(k[Nb])=1
P((k+1)[Nb])=0
P((k+2)[Nb])=−1
P((k+3)[Nb])=0
where “[Nb]” means modulo Nb.

2. The method as claimed in claim 1, characterized in that the useful signal (Vu) is low-pass filtered after demodulation.

3. A switching Hall-effect sensor (10) comprising a Hall cross including two orthogonal branches (120, 122), characterized in that it comprises means configured to measure a useful signal (Vu) representing the magnetic field in which said Hall cross is placed, by carrying out a method according to claim 1.

4. A motor vehicle, characterized in that it comprises a switching Hall-effect sensor as claimed in claim 3.

5. A switching Hall-effect sensor (10) comprising a Hall cross including two orthogonal branches (120, 122), characterized in that it comprises means configured to measure a useful signal (Vu) representing the magnetic field in which said Hall cross is placed, by carrying out a method according to claim 2.
